(19) United States
(12) Patent Application Publication
(10) Pub. No.: US 2007/0126099 A1
(43) Pub. Date: Jun. 7, 2007

(54) MEMORY CARD

(75) Inventors: Yoshitaka Aoki, Kanagawa (JP); Keiichi Tsutsui, Kanagawa (JP); Hirotaka Nishizawa, Tokyo (JP); Tamaki Wada, Saitama (JP)

Correspondence Address: BELL, BOYD & LLOYD, LLP, P. O. BOX 1135, CHICAGO, IL, 60690, US

(73) Assignee: SONY CORPORATION, Tokyo (JP)

(21) Appl. No.: 11/565,788

(22) Filed: Dec. 1, 2006

(30) Foreign Application Priority Data
Dec. 2, 2005 (JP) P2005-349699

(51) Int. Cl. H01L 23/02

(52) U.S. Cl. 257/679

(57) ABSTRACT

To provide a memory card advantageous for coping with an increase of storage capacity. As an embodiment of the present invention, a memory card is formed in a rectangular thin-plate form, by a housing that is made of an insulated material and in that a recessed part is formed on the top surface being one surface in the thickness direction, and a rectangular multi-chip package contained in the recessed part. The housing has a rectangular bottom wall and side walls standing from three of the four sides of the bottom wall. In these side walls, two side walls face to each other, and the remaining one side wall connects one end part of these side walls. The recessed part is formed to be open upward and sideward by the bottom wall and the three side walls.

### CROSS REFERENCE TO RELATED APPLICATION

The present application claims priority to Japanese Patent Application JP2005-349699 filed in the Japanese Patent Office on Dec. 2, 2005, the entire contents of which being incorporated herein by reference.

### BACKGROUND

The present application generally relates to a memory card. A memory card which has a data rewritable flash memory, and in that data is written and read to/from this flash memory has been provided.

As such memory card, there has been provided that is formed in a rectangular thin-plate form, by a housing that is made of an insulated material and in that a recessed part open upward and rectangular in a plane view is formed on the top surface being one surface in the thickness direction, and a rectangular multi-chip package that includes a flash memory and is contained in the recessed part (see Japanese Patent Laid-Open No. 2001-338274).

In this memory card, the housing has a rectangular bottom wall and side walls standing from the four sides of the bottom wall, and four side surfaces of the memory card are formed by the four side walls of the housing.

In recent years, because an increase of the storage capacity of a memory card has been required, the size of a flash memory to be set in a multi-chip package has been increased, and the outer dimension of the multi-chip package has been increased.

On the other hand, the outer dimension of a housing is fixed by the specifications of a memory card. Therefore, there is a limit in the size of a multi-chip package that can be contained in the recessed part of a housing.

### SUMMARY

According to an embodiment of the present invention, there is provided a memory card formed in a rectangular thin-plate form, by a housing that is made of an insulated material and in that a recessed part is formed on the top surface being one surface in the thickness direction, and a rectangular multi-chip package contained in the above recessed part. The above housing has a rectangular bottom wall, and side walls standing from three of the four sides of the bottom wall. The above recessed part is formed to be open upward and sideward by the bottom wall and the three side walls. And the above multi-chip package extends on the whole area of the above bottom wall in the recessed part.

The nature, principle and utility of the present invention will become more apparent from the following detailed description when read in conjunction with the accompanying drawings in which like parts are designated by like reference numerals or characters.

Additional features and advantages are described herein, and will be apparent from, the following Detailed Description and the figures.

### BRIEF DESCRIPTION OF THE FIGURES

FIG. 1 is a perspective view of a memory card 10.

FIGS. 2A and 2B are exploded perspective views of the memory card 10.

FIG. 3 is a view of an arrow A in FIG. 1.

FIG. 4 is a sectional view by a line BB in FIG. 1.

FIG. 5 is a perspective view of a housing 12.

FIG. 6 is a perspective view of a multi-chip package 14.

FIG. 7 is a perspective view of the multi-chip package 14.

FIG. 8A is a plan view of the multi-chip package 14, and FIG. 8B is a sectional view by a line BB in FIG. 8A.

FIG. 9 is a diagram showing correspondence between a connecting piece 36 on the memory card 10 and a signal name.

FIG. 10A is a plan view of a multi-chip package 14 of a memory card 10 of a second embodiment, and FIG. 10B is a sectional view by a line BB in FIG. 10A.

FIG. 11A is a plan view of a multi-chip package 14 of a memory card 10 of a third embodiment, and FIG. 11B is a sectional view by a line BB in FIG. 11A.

FIG. 12A is a plan view of a multi-chip package 14 of a memory card 10 of a fourth embodiment, and FIG. 12B is a view of an arrow B in FIG. 12A.

FIG. 13A is a perspective view by that a multi-chip package 14 of a memory card 10 of a fifth embodiment is inverted upside down, FIG. 13B is a perspective view of the multi-chip package 14, and FIG. 13C is a perspective view of a housing 12.

FIG. 14A is a perspective view by that a multi-chip package 14 of a memory card 10 of a sixth embodiment is inverted upside down, FIG. 14B is a perspective view of the multi-chip package 14, and FIG. 14C is a perspective view of a housing 12.

FIG. 15 is a perspective view of a memory card 10 of a seventh embodiment.

FIGS. 16A and 16B are diagrams showing examples of correspondence between a connecting piece 36 of the memory card 10 of a seventh embodiment and a signal name.

### DETAILED DESCRIPTION

Preferred embodiments of the present invention will be described with reference to the accompanying drawings:

A first embodiment will be described with reference to the accompanying drawings.

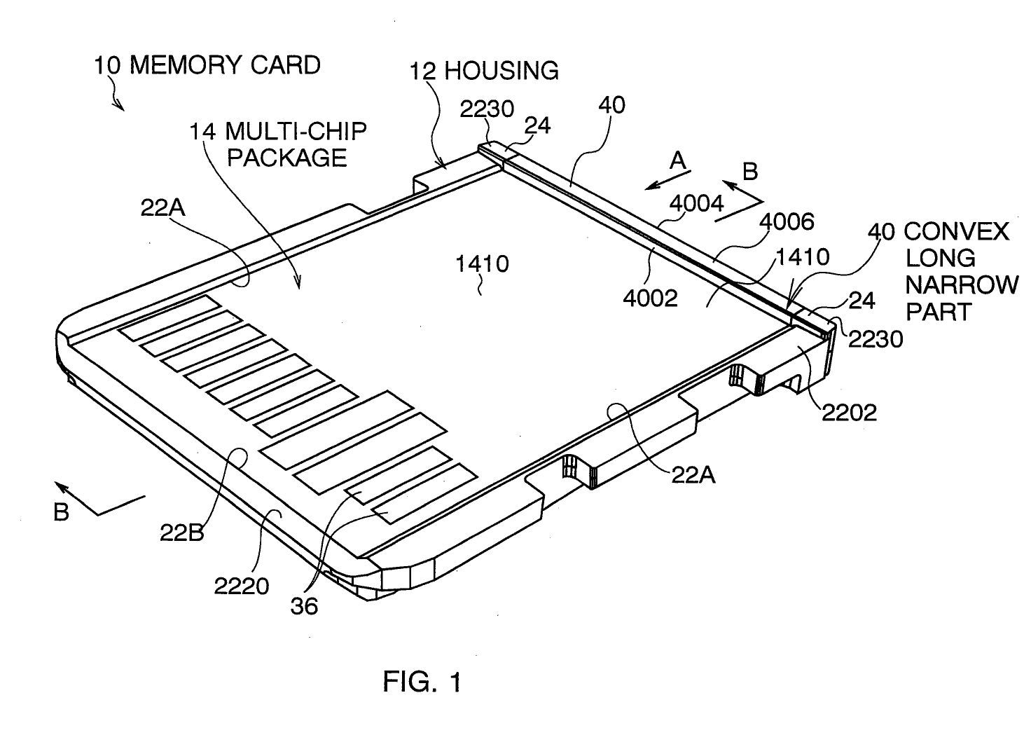

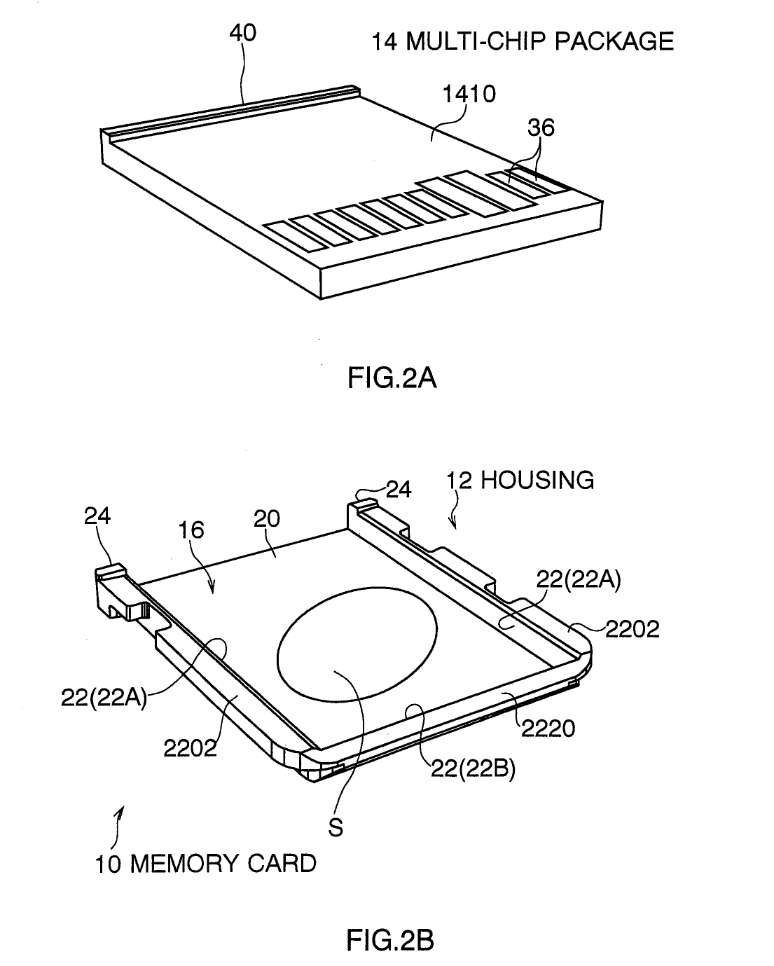

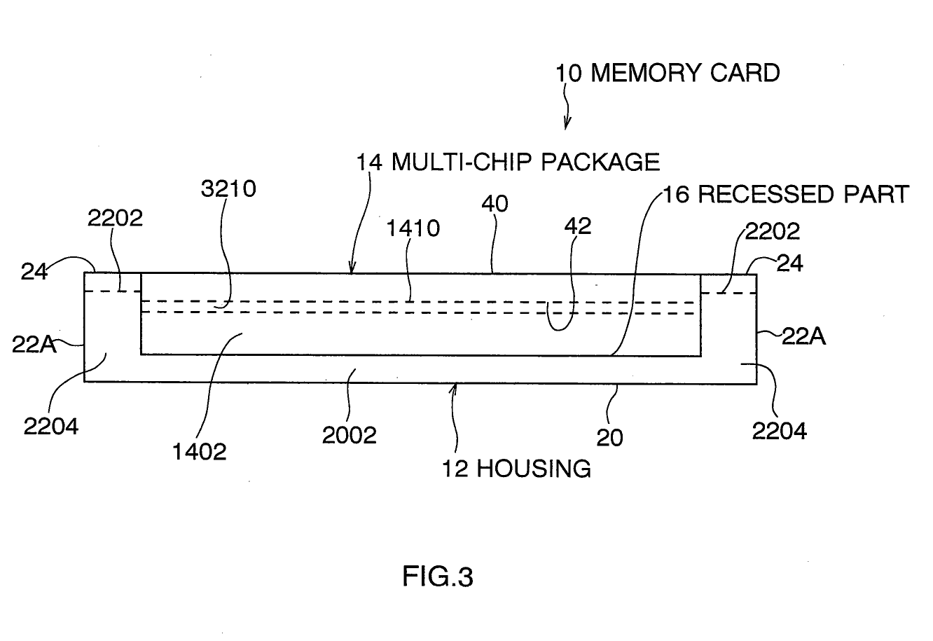

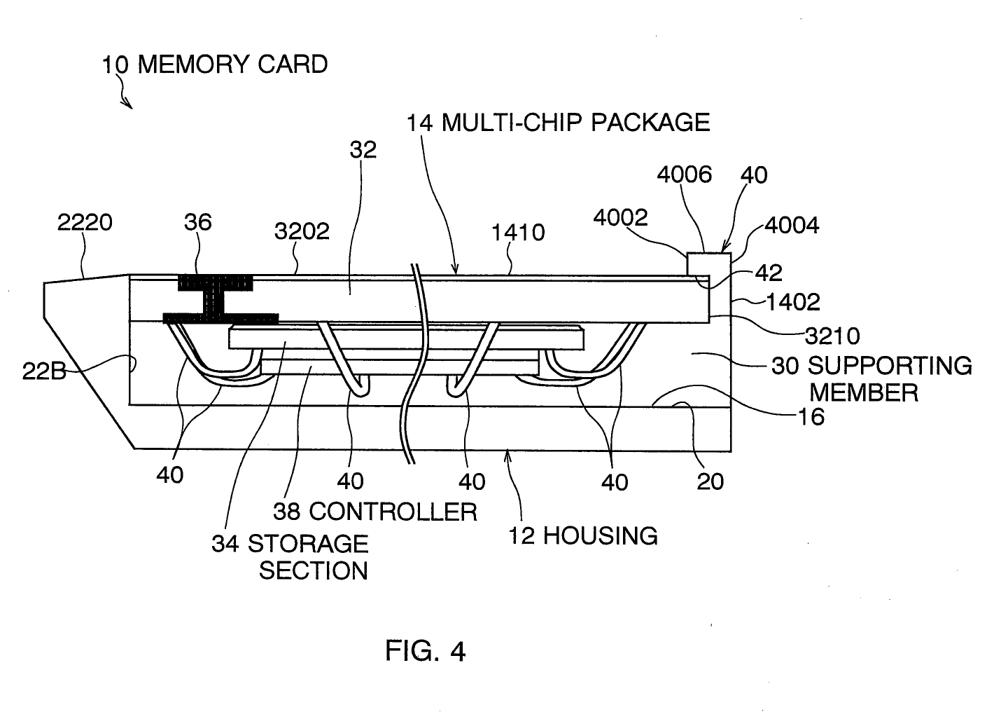

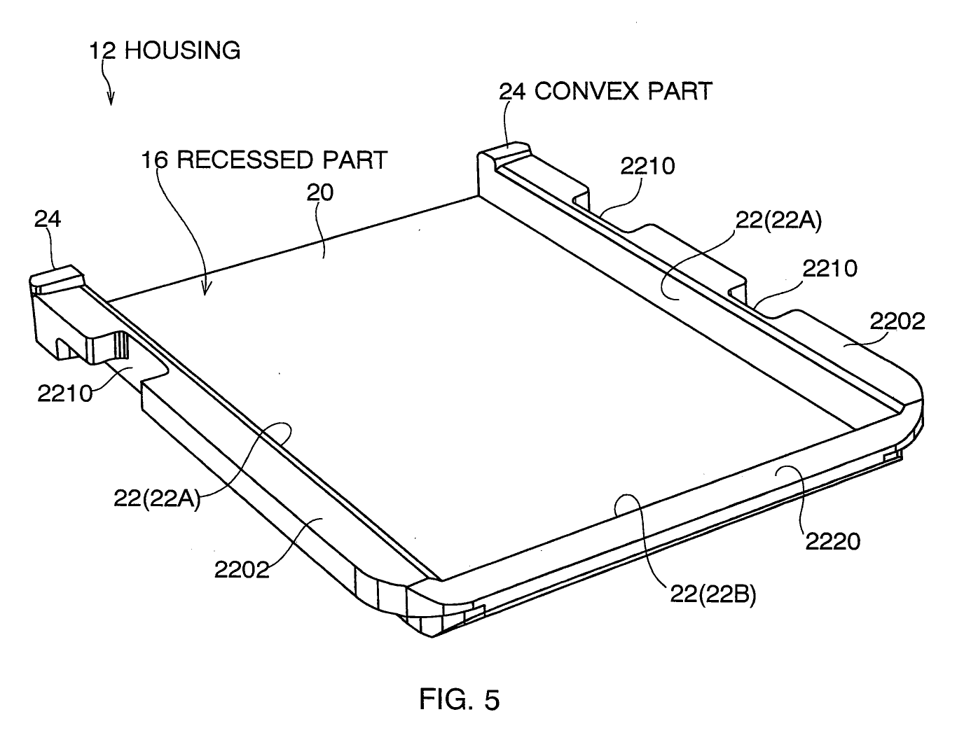

FIG. 1 is a perspective view of a memory card 10. FIGS. 2A and 2B are exploded perspective views of the memory card 10. FIG. 3 is a view of an arrow A in FIG. 1. FIG. 4 is a sectional view by a line BB in FIG. 1. And FIG. 5 is a perspective view of a housing 12.

Note that, in this specification, a memory card 10 designates MEMORY STICK MICRO (a registered trademark of Sony Corporation) according to an embodiment.

As shown in FIGS. 1, 2A and 2B, the memory card 10 is made of an insulated material. It is formed in a rectangular thin-plate form, by the housing 12 in that a recessed part 16 is formed on the top surface being one surface in the thickness direction, and a rectangular multi-chip package 14 contained in the recessed part 16.

As the insulated material forming the housing 12, for example, thermoplastic resin such as polycarbonate and polybutylene terephthalate can be used.

As shown in FIG. 5, the housing 12 has a rectangular bottom wall 20, and side walls 22 that stand from three of the four sides of the bottom wall 20. In these side walls 22, two side walls 22A face to each other, and the remaining one side wall 22B connects one end part of these two side walls 22A.

The recessed part 16 is formed to be open upward and sideward by the bottom wall 20 and the three side walls 22.

At the end parts of the side walls 22A facing to each other, a convex parts 24 which project more upward than the top surfaces 2202 of the remaining side walls 22A except the above end parts are formed.

On the outer side surfaces of the side walls 22A facing to each other, a recessed part 2210 is formed so that when this memory card 10 was inserted into a card connector (card slot) provided in an external device, lock mechanism to lock the insertion state of the memory card 10 is engaged with that.

The multi-chip package 14 extends on the whole area of the bottom wall 20 in the recessed part 16.

Then, as shown in FIGS. 1 and 3, three of the four side surfaces of the memory card 10 are formed by the side walls 22 (22A, 22B) of the housing 12, and the remaining one side surface is formed by the end surface 2002 of the bottom wall 20, the end surfaces 2204 of the two side walls 22A facing to each other, and a side surface 1402 of the multi-chip package 14 contained in the recessed part 16.

As shown in FIG. 1, the end surface 2002 of the bottom wall 20 being the remaining one side surface, the end surfaces 2204 of the two side walls 22A, and the side surface 1402 of the multi-chip package 14 extend on the same plane.

The top surface of the multi-chip package 14 is formed by a flat plane 1410 extending on the remaining part except a part along one side of the multi-chip package 14 on the bottom wall 20 on which the side walls 22 (22A, 22B) do not stand, and a convex long narrow part 40 for finger hook that extends along the above one side higher than the flat plane 1410 at the part along the one side of the multi-chip package 14.

The multi-chip package 14 has a holding member 30 in a rectangular thin-plate form made of an insulated material (see FIG. 4), and a board 32 (see FIG. 4) that is disposed on the holding member 30, and in that a storage section 34 (see FIG. 4) writable and/or readable data is formed. The flat plane 1410 is formed on the top surface of the board 32, and a connecting piece 36 is formed on the top surface of the board 32.

More specifically, a plurality of connecting pieces 36 are provided in line on the flat plane 1410, at a part of the side facing to the convex long narrow part 40, along the above side.

As shown in FIG. 4, the convex long narrow part 40 has an inner side surface 4002 facing the flat plane 1410, an external side surface 4004 being on the opposite side to the inner side surface 4002 and forming one side surface 1402 of the multi-chip package 14, and a top end surface 4006 connecting these inner side surface 4002 and external side surface 4004.

As shown in FIGS. 3 and 4, on the convex long narrow part 40, a groove 42 from the inner side surface 4002 toward the external side surface 4004 is formed as extending along the extending direction of the convex long narrow part 40. The end part 3210 of the board 32 is inserted into the groove 42.

As shown in FIG. 1, the top surface 2202 of the two side walls 22A except the end parts (convex parts 24) of the two side walls 22A at the both ends of the convex long narrow part 40 in the extending direction are each formed to be higher than the flat plane 1410 of the multi-chip package 14.

The top surface 2230 of the end parts (convex parts 24) of the two side walls 22A at the both ends of the convex long narrow part 40 in the extending direction are each formed to be higher than the top surfaces 2202 and 2220 of the three side walls 22A and 22B except each the end parts of the two side walls 22A, and to be as high as the top surface 4006 of the convex long narrow part 40.

As shown in FIGS. 1 and 4, the top surface 2220 of the side wall 22B facing to the convex long narrow part 40 is formed successively to the flat plane 1410 of the multi-chip package 14, so that the memory card 10 can be smoothly inserted into the card connector and the card slot of an external device.

Note that, in this embodiment, to aim for the aforementioned smooth insertion, the top surface 2220 is formed in a slant surface in that as it goes to the top end, it becomes low. However, this slant surface may be formed successively from the top surface 2220 to the end part of the flat plane 1410.

Next, the multi-chip package 14 will be described in detail.

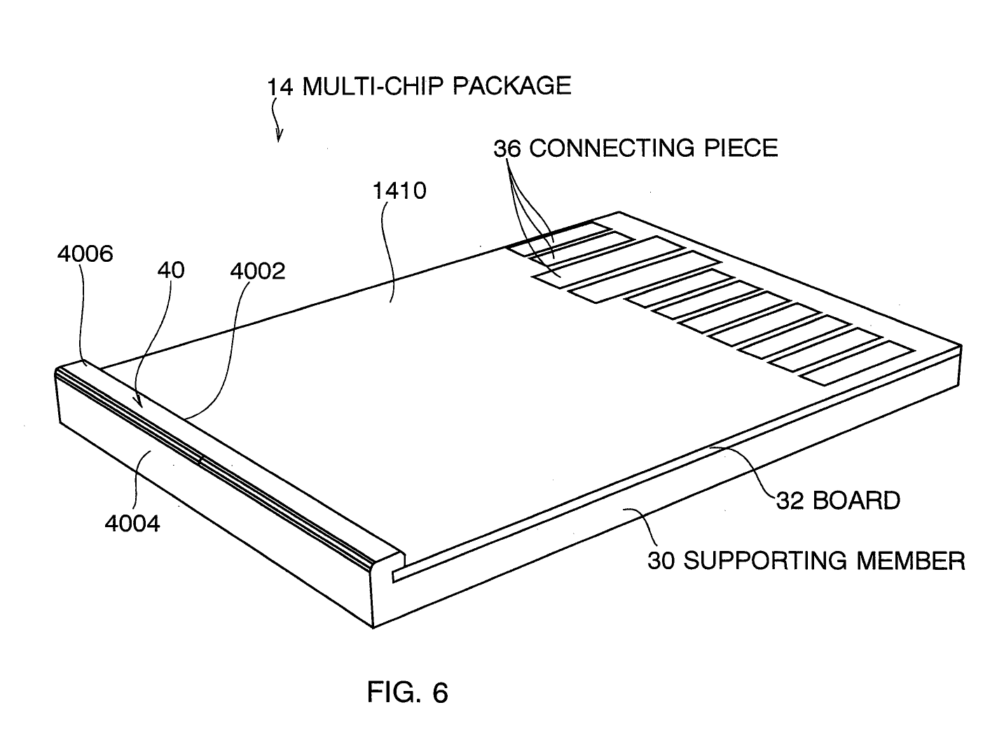

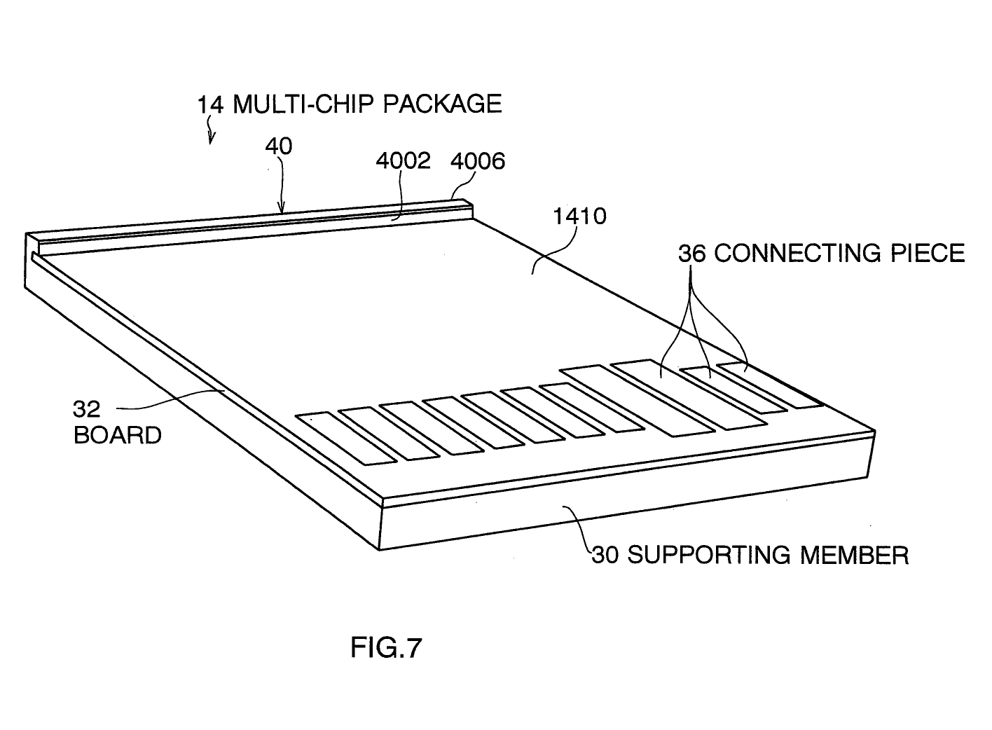

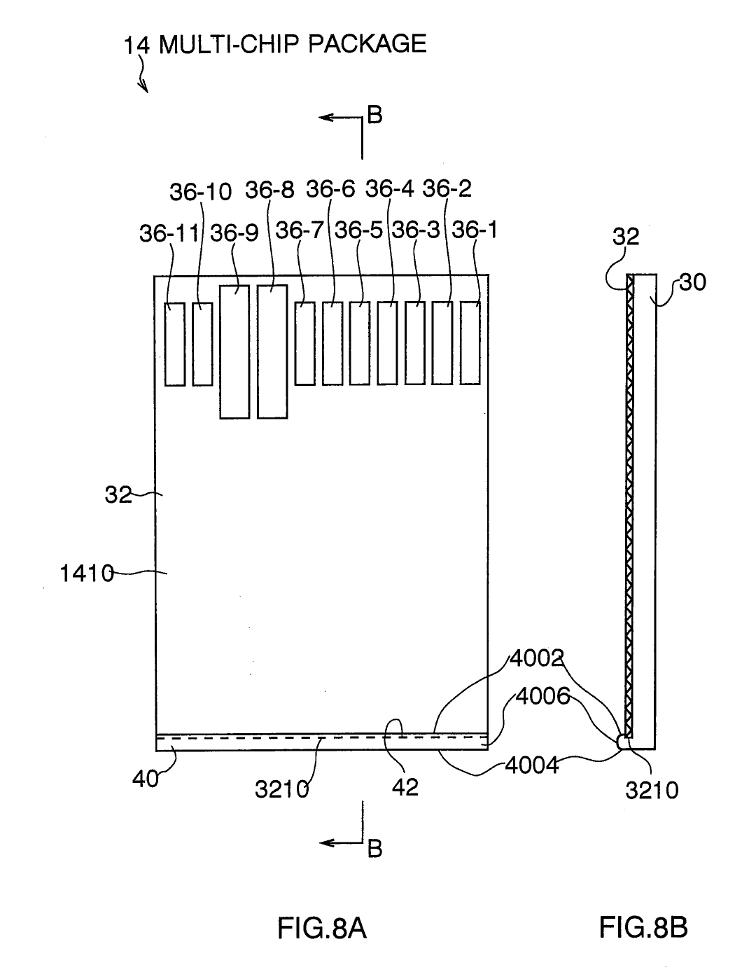

FIGS. 6 and 7 are perspective views of the multi-chip package 14. FIG. 8A is a plan view of the multi-chip package 14, and FIG. 8B is a sectional view by a line BB in FIG. 8A.

As shown in FIG. 4, the multi-chip package 14 has a controller 38 in addition to the aforementioned holding member 30, board 32, storage section 34 and plurality of connecting pieces 36.

As an insulated material forming the holding member 30, for example, thermoset as epoxy resin including glass fiber can be used.

The board 32 is formed in a rectangular thin-plate form from an insulated material. A conducting pattern is formed on its surface or inside, and it is on the top surface of the holding member 30.

The storage section 34 is provided as buried in the holding member 30 in the state where it is attached to the bottom surface of the holding member 32, and data can be written and/or read to/from it. In this embodiment, the storage section 34 is a data rewritable flash memory.

The connecting piece 36 is provided on the top surface being one surface of the holding member 30 in the thickness direction. Concretely, a part of the board 32 except the top surface is provided as buried in the holding member 30, and the connecting piece 36 is formed as penetrating the board 32 from the top surface to the bottom surface. The surface (top surface) of the board 32 is covered with a resist 3202 made of an insulated material. On the resist 3202, a part corresponding to the connecting piece 36 is opened, and the connecting piece 36 is exposed outward via this opening.

The controller 38 performs data communication with an external device via the connecting piece 36 provided as buried in the holding member 30, and data writing and/or reading to/from the storage section 34 is performed. In this embodiment, the controller 38 is provided as buried at a part of the holding member 30 on the storage section 34. However, the controller 38 may be provided as buried at a part of the holding member 30 on the board 32.

Note that, in FIG. 4, the reference numeral 40 designates bonding wires that electrically connect between the storage section 34 and the pattern of the board 32, between the controller 38 and the pattern of the board 32, between the storage section 34 and the connecting piece 36, and between the controller 38 and the connecting piece 36 respectively.

As shown in FIG. 2, the multi-chip package 14 is disposed by that its bottom surface is attached to the bottom wall 20 of the recessed part 16 by adhesive S, and extends on the whole area of the bottom wall 20 in the recessed part 16.

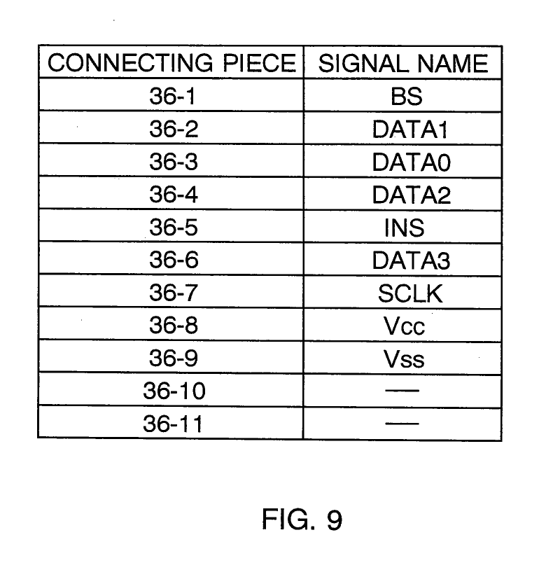

FIG. 9 is a diagram showing correspondence between the connecting piece 36 on the memory card 10 and a signal name.

As shown in FIG. 8A, the connecting piece 36 is formed by eleven connecting pieces 36-1 to 36-11. As shown in FIG. 9, the connecting pieces 36-10 and 36-11 are unused, and signals are allocated to the remaining nine connecting pieces.

That is, a plurality of connecting pieces 36 includes a signal terminal for transmitting/receiving a signal to/from the controller 38, a ground terminal for supplying ground potential to the controller 38 and the storage section 34, and a power supply terminal for supplying power to the controller 38 and the storage section 34.

The connecting pieces 36-1 to 36-7 are the above-mentioned signal terminals, the connecting piece 36-8 is the above-mentioned power supply terminal, and the connecting piece 36-9 is the above-mentioned ground terminal.

If explaining in detail, the connecting piece 36-1 is a signal terminal for entering a bus state signal BS showing data segment communicated as data signals DATA0 to DATA3.

The connecting piece 36-2 is a signal terminal for performing input-output of the data signal DATA1, the connecting piece 36-3 is a signal terminal for performing input-output of the data signal DATA0. The connecting piece 36-4 is a signal terminal for performing input-output of the data signal DATA2. The connecting piece 36-6 is a signal terminal for performing input-output of the data signal DATA3.

The connecting piece 36-5 is a connecting piece for detecting insertion and pulling out, and is a signal terminal for transmitting/receiving an INS signal that is used by the above-mentioned external device for detecting insertion and pulling out of a memory card.

The connecting piece 36-7 is a signal terminal for entering a clock signal SLCK. The above-mentioned bus state signal BS and data signals DATA0 to DATA3 are communicated in synchronization with this clock signal SLCK.

The connecting piece 36-8 is a power supply terminal for entering a power source Vcc.

The connecting piece 36-9 is a ground terminal that is connected to a ground level (Vss).

Note that, the unused connecting pieces 36-10 and 36-11 are provided for expansion.

According to this embodiment, a recessed part 16 formed in a housing 12 is formed to be open upward and sideward by a bottom wall 20 and three side walls 22, and a multi-chip package 14 extends on the whole area of the bottom wall 20 in this recessed part 16. Since one side wall is less than a conventional memory card, a large area can be kept for a board 32 (multi-chip package 14). Therefore, a memory card 10 that although it is the same size as a conventional memory card, it has a storage section 34 (multi-chip package 14) in that the storage capacity is increased and the outer dimension is larger than conventional one can be obtained, or a memory card 10 that although the size is smaller than the conventional memory card, it has a storage section 34 having the same storage capacity as the conventional one can be obtained.

Furthermore, since the convex long narrow part 40 for finger hook is provided on the top surface of the multi-chip package 14, attachment/detachment of the memory card 10 can be performed readily. Moreover, since the groove 42 is provided on this convex long narrow part 40 for inserting the end part 3210 of the board 32, it is further advantageous for keeping the area of the board 32.

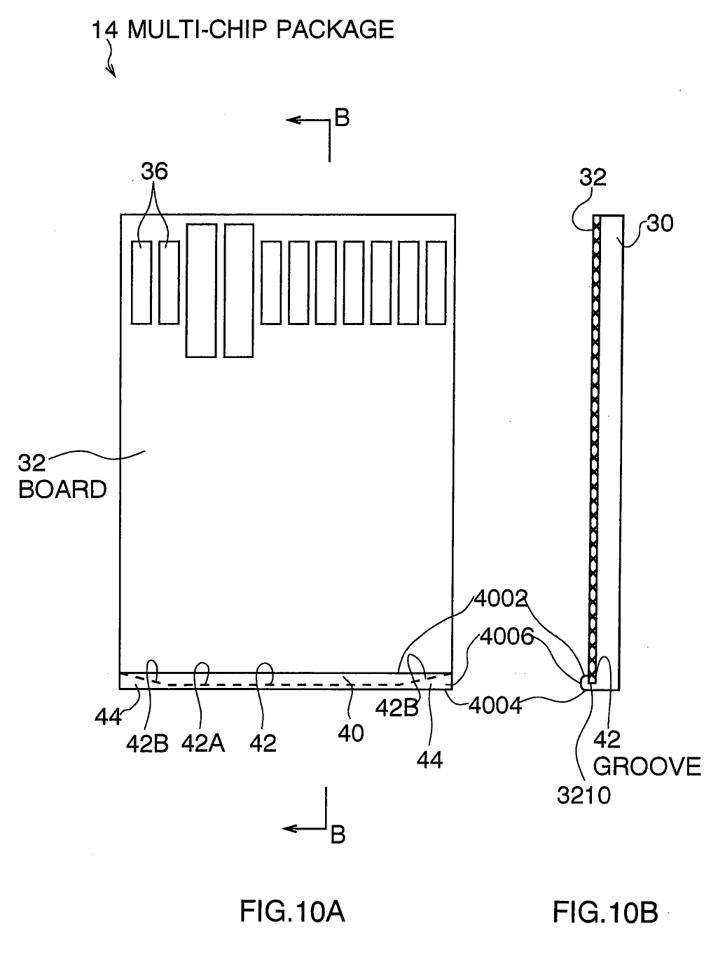

FIG. 10A is a plan view of a multi-chip package 14 of a memory card 10 of a second embodiment, and FIG. 10B is a sectional view by a line BB in FIG. 10A. Note that, the following embodiments will be described by adding the same reference numerals to parts and members similar to the first embodiment.

The second embodiment is different from the first embodiment in the shape of the groove 42 for inserting the end part 3210 of the board 32.

Specifically, in the first embodiment, the groove 42 is formed as extending along the whole length of the convex long narrow part 40. On the other hand, in the second embodiment, the groove 42 is provided along a part except the both ends of a convex long narrow part 40 in the extending direction.

If explaining in detail, the groove 42 is formed by a first groove part 42A that extends at a depth of a larger value than the first embodiment at the center part of the convex long narrow part 40 in the extending direction, and second groove parts 42B in which the depth becomes gradually smaller from the both ends of the first groove part and is connected to an inner side surface 4002.

According to the second embodiment, it is further advantageous for keeping the area of the board 32 by the first groove part 42A. Moreover, the strength of the convex long narrow part 40 can be maintained by side wall parts 44 forming the back part of the second groove parts 42B.

Of course, also in this second embodiment, similar effect to the first embodiment can be obtained.

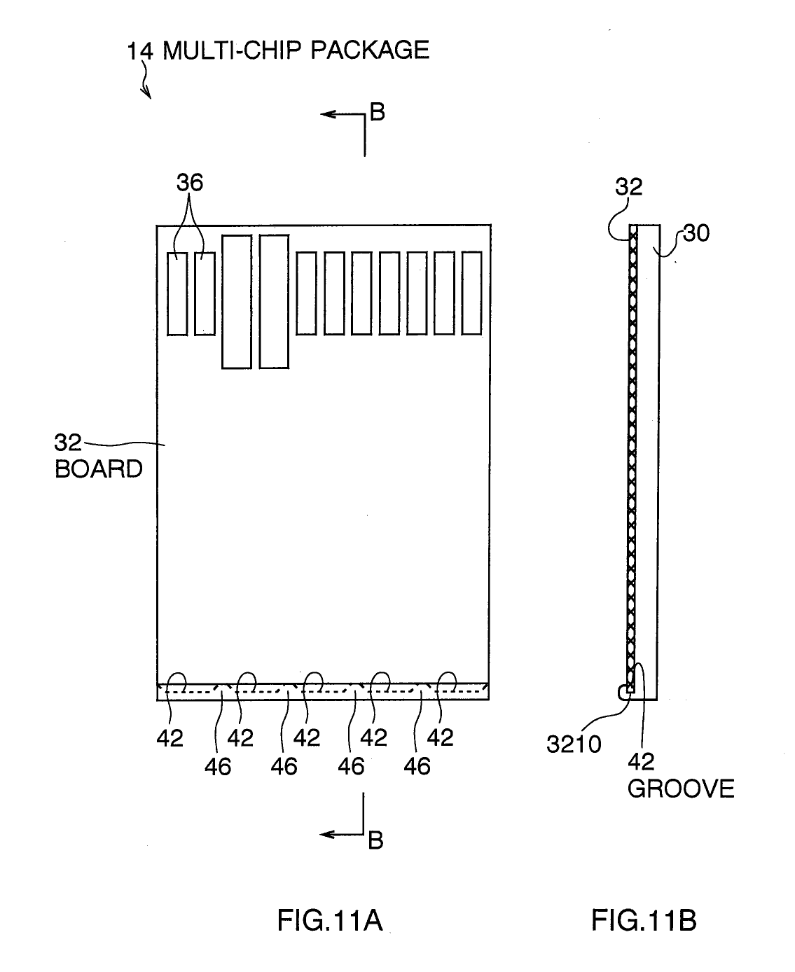

FIG. 11A is a plan view of a multi-chip package 14 of a memory card 10 of a third embodiment, and FIG. 11B is a sectional view by a line BB in FIG. 11A.

The third embodiment is different from the first embodiment in the shape of the groove 42 for inserting the end part 3210 of the board 32.

Specifically, in the first embodiment, the groove 42 is formed as extending along the whole length of the convex long narrow part 40. On the other hand, in the third embodiment, a plurality of grooves 42 are formed at intervals in the extending direction of a convex long narrow part 40.

If explaining in detail, each groove 42 is formed as extending at a depth of a larger value than the first embodiment, and there is a wall part 46 between each the grooves 42.

Then, a part of the end part 3210 of the board 32 corresponding to each groove 42 is inserted to each groove 42.

According to the third embodiment, it is further advantageous for keeping the area of the board 32 by a plurality of grooves 42. Moreover, the strength of the convex long narrow part 40 can be maintained by the wall parts 46.

Of course, also in this third embodiment, similar effect to the first embodiment can be obtained.

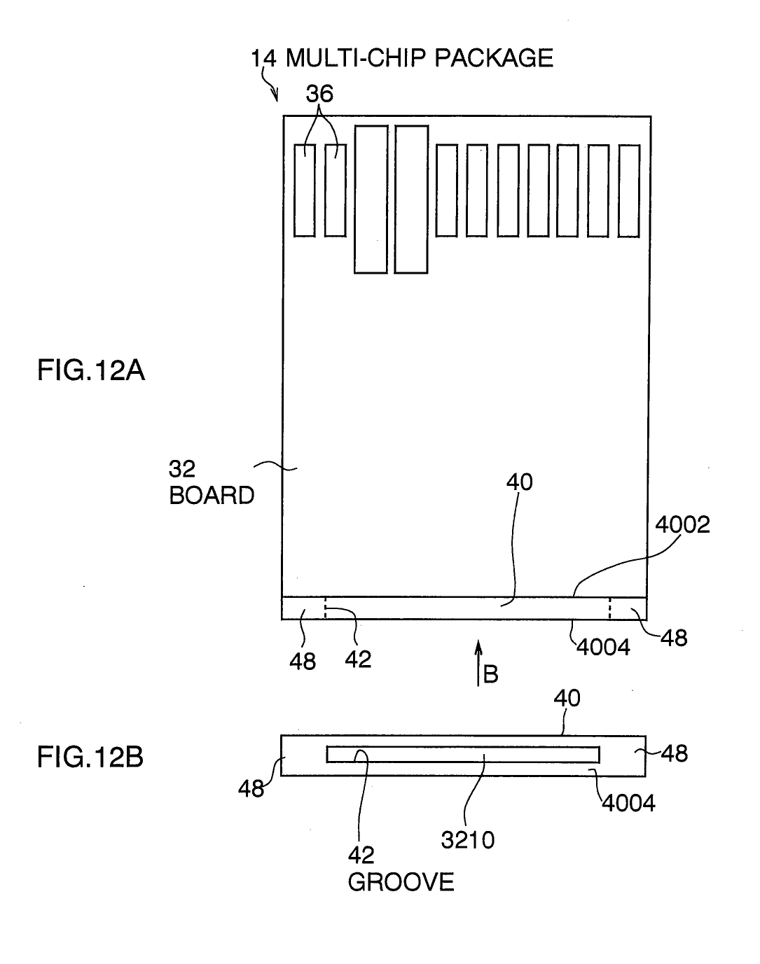

FIG. 12A is a plan view of a multi-chip package 14 of a memory card 10 of a fourth embodiment, and FIG. 12B is a view of an arrow B in FIG. 12A.

The fourth embodiment is different from the first embodiment in the shape of the groove 42 for inserting the end part 3210 of the board 32.

Specifically, a groove 42 is formed as penetrating from the inner side surface toward the outer side surface with remaining the both ends of the convex long narrow part 40 in the extending direction, and a wall part 48 remains at the both ends of the groove 42 in the extending direction.

Then, a part corresponding to the groove 42 in the end part 3210 of the board 32 is inserted into the groove 42, and the above part is on the same plane as an external side surface 4004.

According to the fourth embodiment, it is further advantageous for keeping the area of the board 32 by the groove 42. Moreover, the strength of the convex long narrow part 40 can be maintained by the wall parts 48.

Of course, also in this fourth embodiment, similar effect to the first embodiment can be obtained.

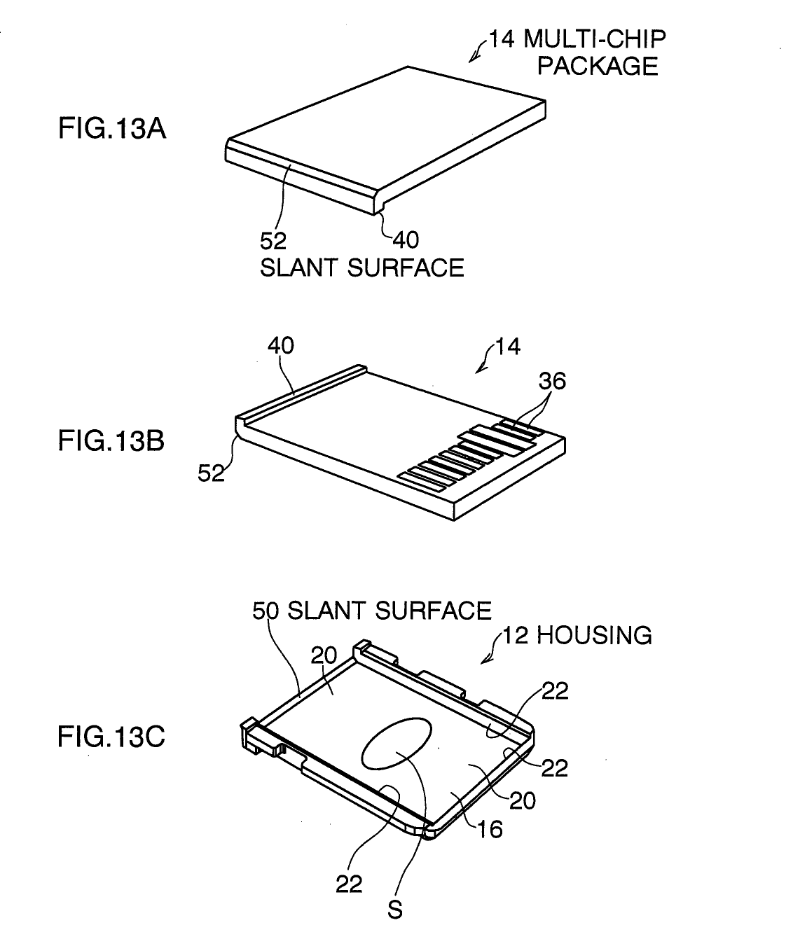

FIG. 13A is a perspective view by that a multi-chip package 14 of a memory card 10 of a fifth embodiment is inverted upside down, FIG. 13B is a perspective view of the multi-chip package 14, and FIG. 13C is a perspective view of a housing 12.

The fifth embodiment is that the multi-chip package 14 is further strongly attached to the housing 12.

Specifically, as shown in FIG. 13C, on one side of a bottom wall 20 that does not have a side wall 22, a slope surface 50 (housing-side engaging part) projecting upward from the bottom wall 20 is formed as expanded along the one side.

On the other hand, as shown in FIGS. 13A and 13B, at a part of the bottom surface of the multi-chip package 14 under a convex long narrow part 40, a slope surface 52 (package-side engaging part) engageable with the projection 50 is formed as extending.

Then, when the bottom surface of the multi-chip package 14 is attached to the bottom wall 20 of a recessed part 16 by adhesive S, the slope surfaces 50 and 52 are engaged with each other, so that the attachment of the multi-chip package 14 to the housing 12 becomes further strong. Furthermore, by that the slope surfaces 50 and 52 are engaged, it is advantageous for readily performing the positioning of the multi-chip package 14 to the housing 12.

Of course, also in this fifth embodiment, similar effect to the first embodiment can be obtained.

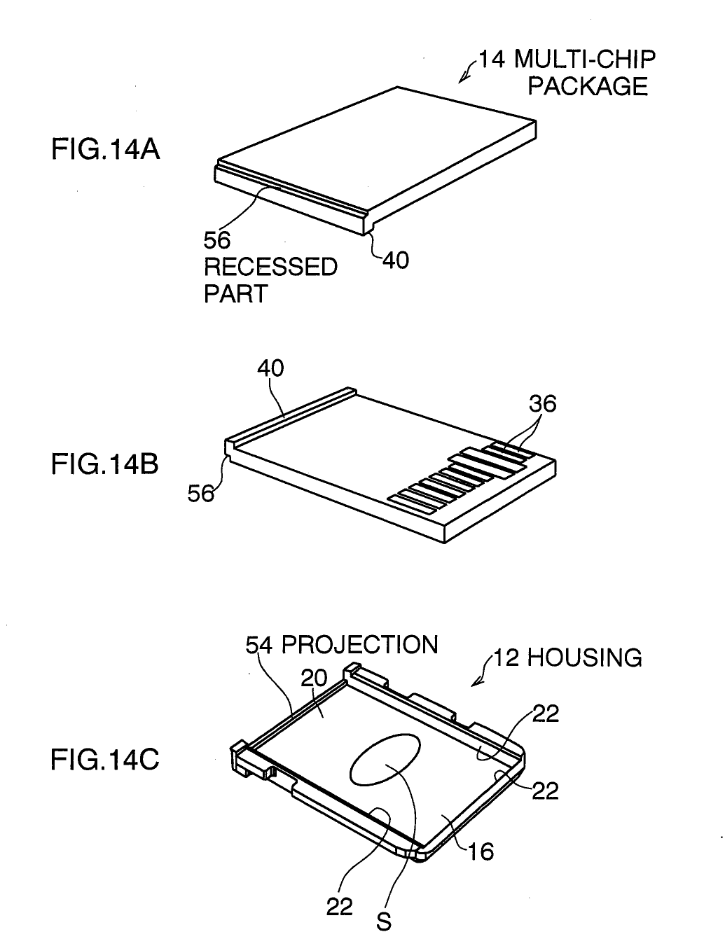

FIG. 14A is a perspective view by that a multi-chip package 14 of a memory card 10 of a sixth embodiment is inverted upside down, FIG. 14B is a perspective view of the multi-chip package 14, and FIG. 14C is a perspective view of a housing 12.

The sixth embodiment is that the multi-chip package 14 is further strongly attached to the housing 12.

Specifically, on one side of a bottom wall 20 that does not have a side wall 22, a projection 54 (housing-side engaging part) projecting upward from the bottom wall 20 is formed as expended along the one side.

On the other hand, at a part of the bottom surface of the multi-chip package 14 under a convex long narrow part 40, a recessed part 56 (a package-side engaging part) engageable with the projection 54 is formed as extending.

Then, when the bottom surface of the multi-chip package 14 is attached to the bottom wall 20 of a recessed part 16 by adhesive S, the projection 54 is engaged with the recessed part 56, so that the attachment of the multi-chip package 14 to the housing 12 becomes further strong. Furthermore, by that the projection 54 is engaged with the recessed part 56, it is advantageous for readily performing the positioning of the multi-chip package 14 to the housing 12.

Of course, also in this sixth embodiment, similar effect to the first embodiment can be obtained.

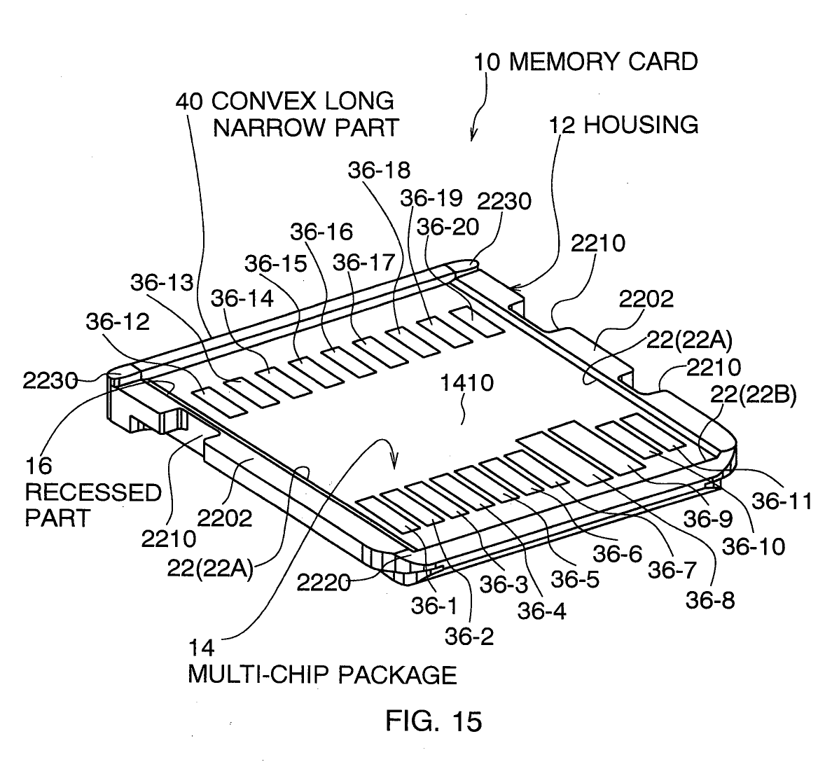

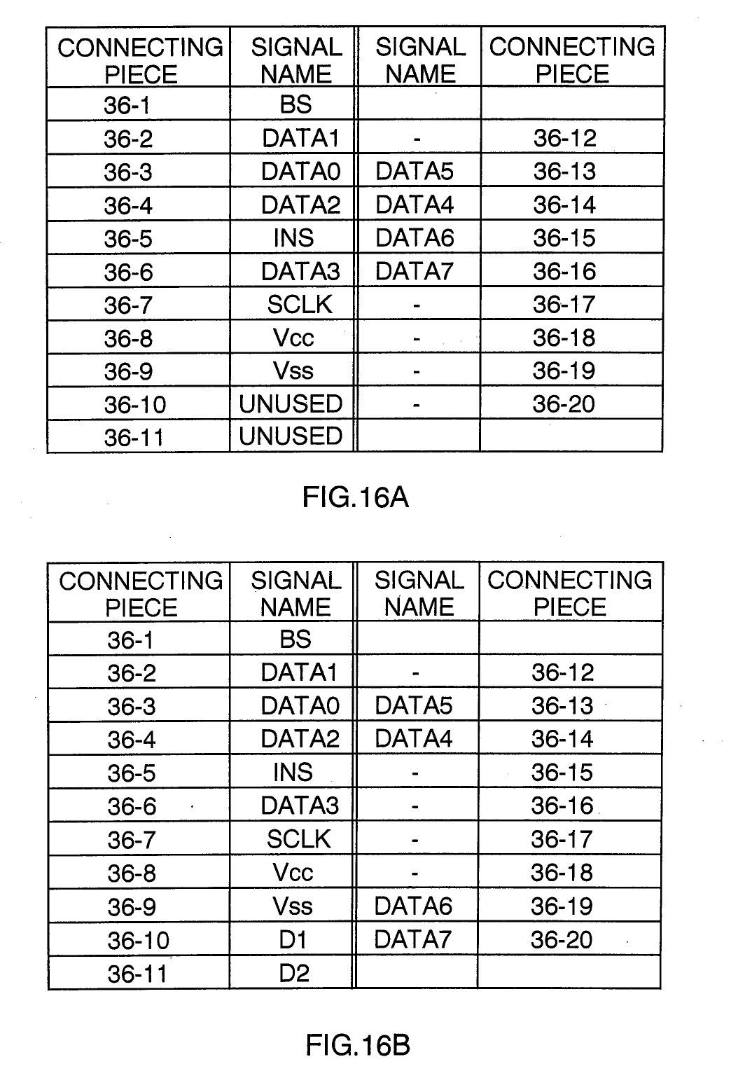

FIG. 15 is a perspective view of a memory card 10 of a seventh embodiment, and FIGS. 16A and 16B are diagrams showing examples of correspondence between a connecting piece 36 of the memory card 10 of the seventh embodiment and a signal name.

The seventh embodiment is that nine connecting pieces 36-12 to 36-20 are newly provided in addition to the connecting pieces 36-1 to 36-11 of the multi-chip package 14. In the first embodiment, the number of communicatable data signals is 4 bit. On the other hand, in the seventh embodiment, the number of communicatable data signal is increased to 8 bit.

Specifically, as shown in FIG. 15, similarly to the first embodiment, the connecting pieces 36-1 to 36-11 are provided in line at the part of a side facing to a convex long narrow part 40 on a flat plane 1410, along the above side. And the connecting pieces 36-12 to 36-20 newly added are provided in line at the part of a side close to the convex long narrow part 40 on the flat plane 1410, along the above side.

In the example shown in FIG. 16A, the connecting piece 36-13 is a signal terminal for performing input-output of DATA5, the connecting piece 36-14 is a signal terminal for performing input-output of DATA4, the connecting piece 36-15 is a signal terminal for performing input-output of DATA6, and the connecting piece 36-16 is a signal terminal for performing input-output of DATA7. The remaining connecting pieces 36-12, and 36-17 to 36-20 are unused.

In the example shown in FIG. 16B, the connecting piece 36-13 is a signal terminal for performing input-output of DATA5, the connecting piece 36-14 is a signal terminal for performing input-output of DATA4, the connecting piece 36-19 is a signal terminal for performing input-output of DATA6, and the connecting piece 36-20 is a signal terminal for performing input-output of DATA7. The remaining connecting pieces 36-12, and 36-15 to 36-18 are unused.

Note that, the allocation of signals to the connecting pieces 36-1 to 36-11 is similar to the example shown in FIG. 9.

According to this seventh embodiment, of course, the number of communicatable data signals can be increased to 8 bit, and also the similar effect to the first embodiment can be obtained.

Note that, in the aforementioned embodiments, it has dealt with the case where the memory card 10 is a Memory Stick Micro. However, the format of a memory card 10 is not limited to them.

Further, in the aforementioned embodiments, it has dealt with the case where a data rewritable flash memory is used as the storage section 34. However, the present application is not only limited to this, provided that it is a storage section 34 writable and/or readable data.

According to an embodiment, in a memory card, a multi-chip package extends on the whole area of a bottom wall in a recessed part formed in a housing, so that one side wall can be reduced in comparison to a conventional memory card. Thus, a larger area can be kept for a multi-chip package. Thereby, a memory card having a multi-chip package that although it is the same size as a conventional memory card, the storage capacity is increased and the outer dimension is larger than conventional one can be obtained. It is advantageous for coping with an increase of storage capacity.

It should be understood that various changes and modifications to the presently preferred embodiments described herein will be apparent to those skilled in the art. Such changes and modifications can be made without departing from the spirit and scope of the present subject matter and without diminishing its intended advantages. It is therefore intended that such changes and modifications be covered by the appended claims.

The invention is claimed as follows:

1. A memory card comprising a rectangular thin-plate defined by a housing that is made of an insulated material and in that a recessed part is formed on a top surface being one surface in a thickness direction, and a rectangular multi-chip package contained in said recessed part, wherein:
said housing has a rectangular bottom wall, and side walls standing from three of four sides of said bottom wall;
said recessed part is formed to be open upward and sideward by said bottom wall and said three side walls; and
said multi-chip package extends on a substantially entire area of said bottom wall in said recessed part.

2. The memory card according to claim 1, wherein
the three of the four side surfaces of said memory card are formed by the side walls of said housing, and the remaining one side surface is formed by an end surface of said bottom wall, the end surfaces of the two side walls facing to each other, and the side surface of said multi-chip package contained in said recessed part.

3. The memory card according to claim 1, wherein
the end surface of said bottom wall, the end surfaces of the two side walls, and the side surface of said multi-chip package, that form said remaining one side surface extend on a same plane.

4. The memory card according to claim 1, wherein
the top surface of said multi-chip package is formed by a flat plane that extends on a remaining part except a part along one side of said multi-chip package on the part of the bottom wall in which said side walls do not stand, and a convex long narrow part for finger hook extending along one side at a height higher than said flat plane, at a part along the above one side of said multi-chip package.

5. The memory card according to claim 4, wherein
a plurality of connecting pieces for transmitting/receiving a signal to/from an external device are provided on said flat plane.

6. The memory card according to claim 4, wherein
a plurality of connecting pieces for transmitting/receiving a signal to/from an external device are provided in line on said flat plane, at a part of a side facing to said convex long narrow part, along a above side.

7. The memory card according to claim 6, wherein:
said multi-chip package has a holding member made of an insulated material in a rectangular thin-plate form, and a board that is disposed on a top surface of said holding member and a storage section writable and/or readable data is formed thereon;
said flat plane is formed on the top surface of said board; and
said connecting pieces are formed on the top surface of said board.

8. The memory card according to claim 4, wherein:
said convex long narrow part has an inner side surface facing said flat plane, an outer side surface that is on the opposite side to said inner side surface and forms one side surface of said multi-chip package, and a top end surface connecting these inner side surface and outer side surface;
said multi-chip package has a holding member made of an insulated material in a rectangular thin-plate form, and a board that is disposed on the top surface of said holding member and a storage section writable and/or readable data is formed thereon;
said flat plane is formed on the top surface of said board;
a groove from said inner side surface to said outer side surface is formed as extending along said convex long narrow part in the extending direction; and
the end part of said board is inserted into said groove.

9. The memory card according to claim 4, wherein:
said convex long narrow part has an inner side surface facing said flat plane, an outer side surface that is on the opposite side to said inner side surface and forms one side surface of said multi-chip package, and a top end surface connecting these inner side surface and outer side surface;
said multi-chip package has a holding member made of an insulated material in a rectangular thin-plate form, and a board that is disposed on the top surface of said holding member and a storage section writable and/or readable data is formed thereon;
said flat plane is formed on the top surface of said board;
a groove penetrating from said inner side surface to said outer side surface is formed as extending along said convex long narrow part in the extending direction; and
a part which is at the end part of said board and corresponds to said groove is inserted into said groove, and said part is on the same plane as said outer side surface.

10. The memory card according to claim 4, wherein
the top surface of a side wall facing to said convex long narrow part is formed successively to the flat plane of said multi-chip package.

11. The memory card according to claim 4, wherein:
the top surface of the two side walls except each end part of these two side walls at the both ends of said convex long narrow part in the extending direction is formed to be higher than the flat plane of said multi-chip package;
the top surface of each end part of the two side walls at the both ends of said convex long narrow part in the extending direction is formed to be higher than the top surface of said three side walls except each end part of said two side walls, and is as high as the top surface of said convex long narrow part; and
the top surface of a side wall facing to said convex long narrow part is formed successively to the flat plane of said multi-chip package.

12. The memory card according to claim 1, wherein:
a housing-side engaging section is provided on one side of said bottom wall in which said side wall does not stand thereon;
a package-side engaging section engageable with said housing-side engaging section is provided at a part corresponding to one side of said bottom wall, on the bottom surface of said multi-chip package facing said bottom wall; and
said housing-side engaging section is engaged with said package-side engaging section.
